(19) United States
(12) Patent Application Publication
(10) Pub. No.: US 2014/0182818 A1
(43) Pub. Date: Jul. 3, 2014

(54) HEAT SINK

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: ZHEN-YU WANG, Kunshan (CN); CHANG-SHEN CHANG, New Taipei (TW); BEN-FAN XIA, Kunshan (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/960,859

(22) Filed: Aug. 7, 2013

(30) Foreign Application Priority Data
Dec. 29, 2012 (CN) 2012105878723

(51) Int. Cl. H05K 7/20

(52) U.S. Cl. CPC H05K 7/20336
USPC 165/104.21

(57) ABSTRACT

A heat sink for dissipating heat generated by an electronic element is provided. The heat sink includes a heat pipe and a conducting member for transferring heat generated by the electronic element to the heat pipe. The conducting member abuts the electronic element, and the conducting member is applied onto the heat pipe to reduce a thickness of the heat sink.

### BACKGROUND

1. Technical Field

The present disclosure relates to heat sinks, and particularly to a heat sink having a heat pipe.

2. Description of Related Art

FIG. 7 illustrates a heat sink 400 for dissipating heat generated by an electronic element 500. The heat sink 400 includes a conducting plate 410 abutting the electronic element 500, and a heat pipe 420 fixed to the conducting plate 410. The conducting plate 410 defines a plurality of holes 430. Fixing members, such as bolts (not shown), extend through the holes 430 to fix the conducting plate 410 to the electronic element 500. A thickness of the heat sink is determined by the thickness of the conducing plate 410 and the thickness of the heat pipe 420. Because the thickness of the heat pipe 420 directly affects the thermal performance of the heat sink 400, only the thickness of the conducting member 410 can be reduced to reduce a thickness of the heat sink 400. However, when the thickness of the conducting plate 410 is reduced to less than 0.35 mm, the conducting plate 420 is no rigid enough to be mounted to the electronic element 500.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of a heat sink in accordance with a first embodiment.

FIG. 2 is similar to FIG. 1, but viewed from another aspect.

FIG. 3 is an explanatory view for showing the heat sink of FIG. 2 being mounted to an electronic element.

FIG. 4 is a perspective view of a heat sink in accordance with a second embodiment.

FIG. 5 is similar to FIG. 4, but viewed from another aspect.

FIG. 6 is an explanatory view for showing the heat sink of FIG. 5 being mounted to an electronic element.

FIG. 7 illustrates a perspective view of a heat sink of the related art.

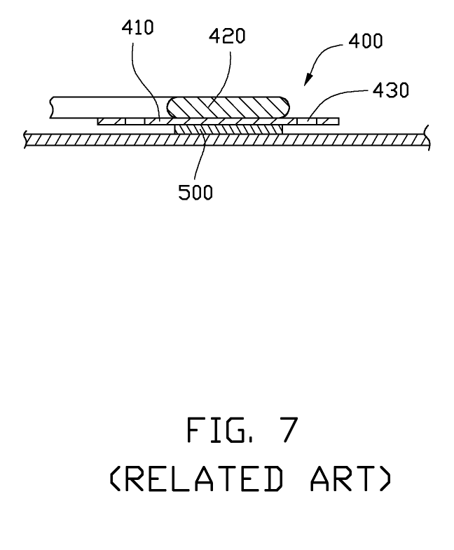

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

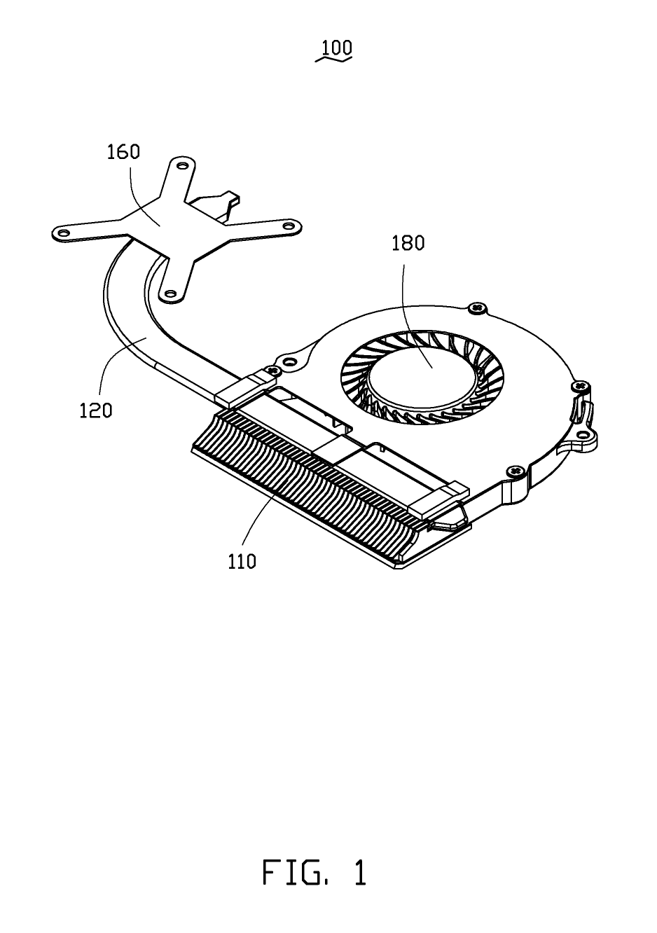

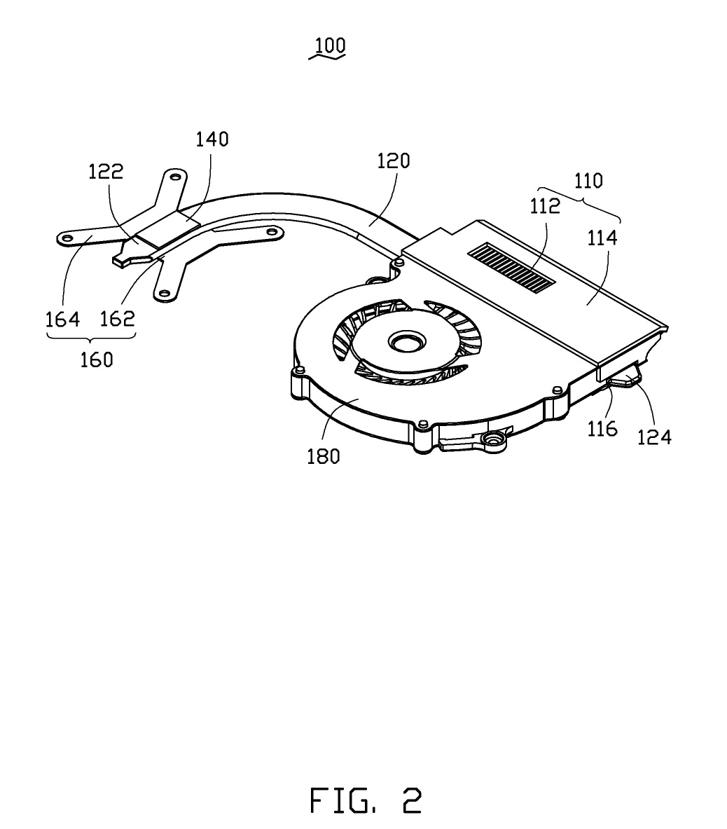

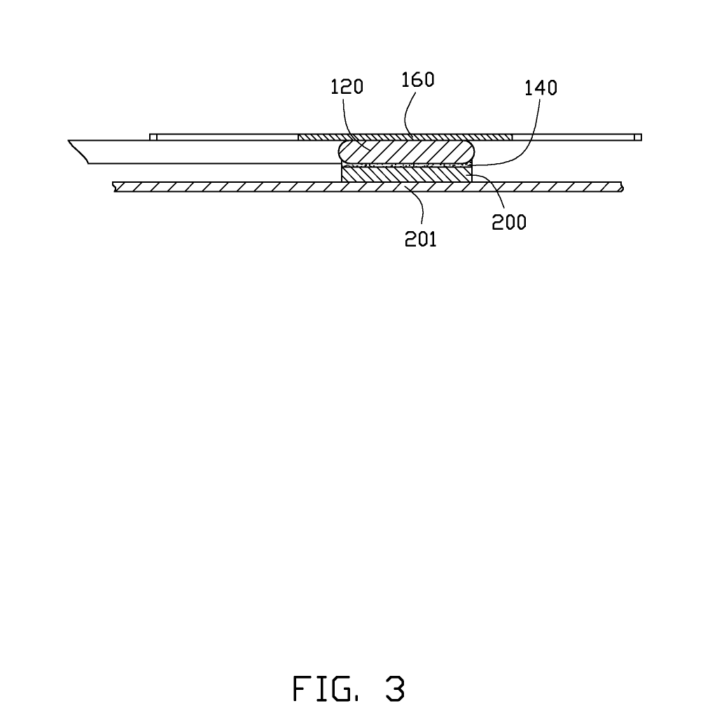

Referring to FIGS. 1 and 2, a heat sink 100 in accordance with a first embodiment is shown. The heat sink 100 dissipates heat generated by an electronic element 200 (see FIG. 3), such as a CPU. The heat sink 100 includes a heat-dissipating module 110, a heat pipe 120 secured to the heat-dissipating module 110, a conducting member 140 covering the electronic element 200 and secured to the heat pipe 120, and a fixing plate 160 for latching the conducting member 140 and the heat pipe 120 to the electronic element 200. The heat sink 100 further includes a fan 180 secured to the heat-dissipating module 110. The fan 180 cools the heat-dissipating module 110.

The heat-dissipating module 110 includes a number of fins 112 and a holding portion 114. The fins 112 are made of metal having a high thermal conduction property, to provide high heat dissipation capability. The fins 112 are arranged parallel to and spaced apart from each other. Each two adjacent fins 112 define a gap (not shown) for providing an air passage. Each of the fins 112 defines a cutout (not show). The cutouts are aligned to form a recess portion 116 for receiving an end of the heat pipe 120. The holding portion 114 is made of plastic material, such as STYROFOAM. The holding portion 114 is adapted to secure the fins 112.

The heat pipe 120 is substantially an arc. The heat pipe 120 is adapted to transfer heat generated by the electronic element 200 to the heat-dissipating module 110. The heat pipe 120 includes a first end 122 adjacent to the electronic element 200, and a second end 124 opposite to the first end 122. The second end 124 is received and mounted in the recess portion 116. The second end 124 in the first embodiment is fixed to the recess portion 116 by soldering.

The conducting member 140 is adapted to transfer heat generated by the electronic element 200 to the heat pipe 120. The heat generated by the electronic element 200 is dissipated by being transferred to the heat-dissipating module 110 via the heat pipe 120. The conducting member 140 is formed by solder or other similar heat conductive bonding agent on a surface of the heat pipe 120 facing the electronic element 200. After attaching solder or the like onto the heat pipe 120, the solder forms the conducting member 140, and is further grounded to form a flat surface for tightly abutting the electronic element 200. A size of the conducting member 140 corresponds to a size of the electronic element 200, and the conducting member 140 covers the electronic element 200. A thickness of the conducting member 140 in the first embodiment is about 0.04 mm.

The fixing plate 160 is substantially X-shaped, and a thickness of the fixing plate 160 is substantially 0.3 mm. The fixing plate 160 includes a base portion 162 and four fixing arms 164. The base portion 162 is substantially rectangular. The base portion 162 is secured to an end of the heat pipe 120 adjacent to the electronic element 200. Therefore, the heat pipe 120 and the conducting member 140 are sandwiched between the base portion 162 and the electronic element 200. The fixing arms 164 are integrally formed with the base portion 162 and extend coplanarly from four corners of the base portion 162. An end of each fixing arm 164 away from the base portion 162 defines a through hole (not labeled). The through holes receive fixing members, such as bolts (not shown), to mount the fixing plate 160 to a base 201 where the electronic element 200 is mounted.

Also referring to FIG. 3, in assembly, the second end 124 of the heat pipe 120 is mounted in the recess portion 116 of the heat-dissipating module 110, and the fan 180 is mounted to the base 201 for mounting the electronic element 200. The conducting member 140 abuts the electronic element 200, and the fixing plate 160 is mounted to the base 201 by fixing members.

After assembly, the conducting member 140 directly abuts the electronic element 200, heat generated by the electronic element 200 is transferred to the heat pipe 120 via the conducting member 140, and the heat is further transferred to the heat-dissipating module 110. In the present disclosure, the conducting member 140 is applied onto the heat pipe 120, and the thickness of the conducting member 140 is less. Thus, a thickness of the heat sink 100 is reduced.

It is understood that, the fixing plate 160 in the first embodiment can be secured to opposite sides of the heat pipe 120 and does not cover a top surface of the heat pipe 120 opposite to the conducting member 140.

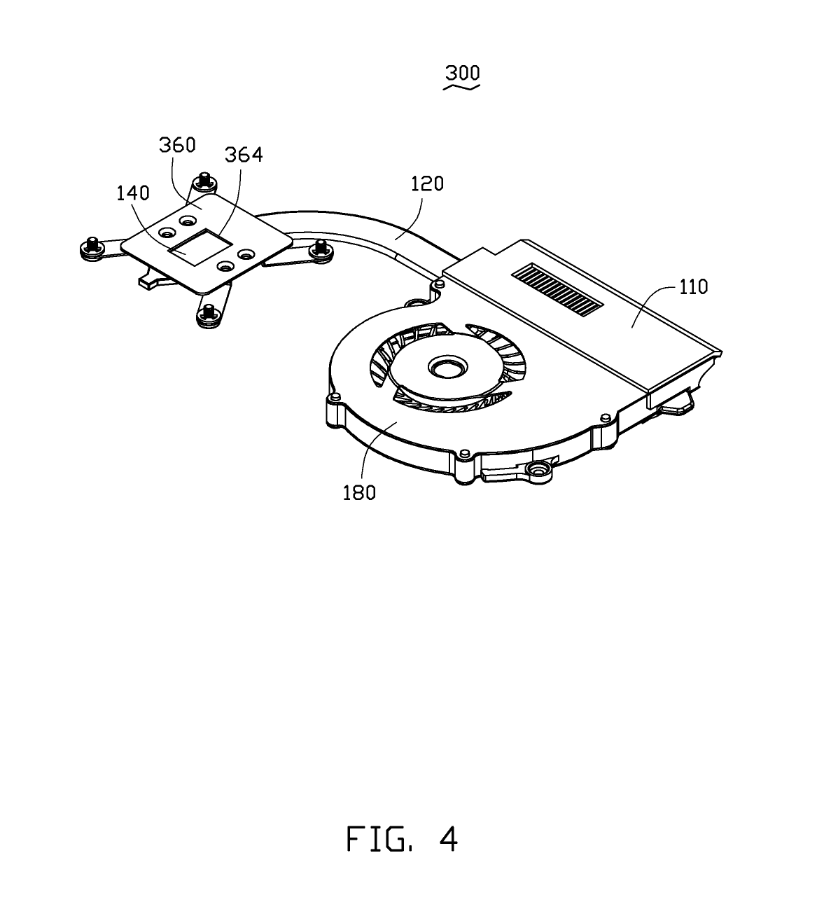

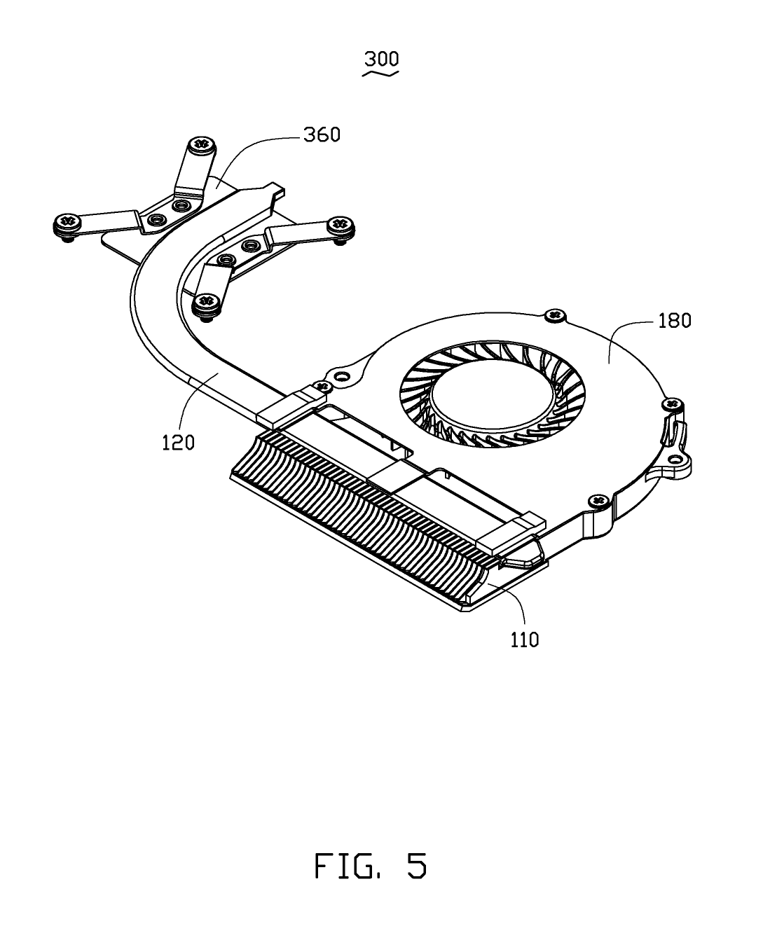

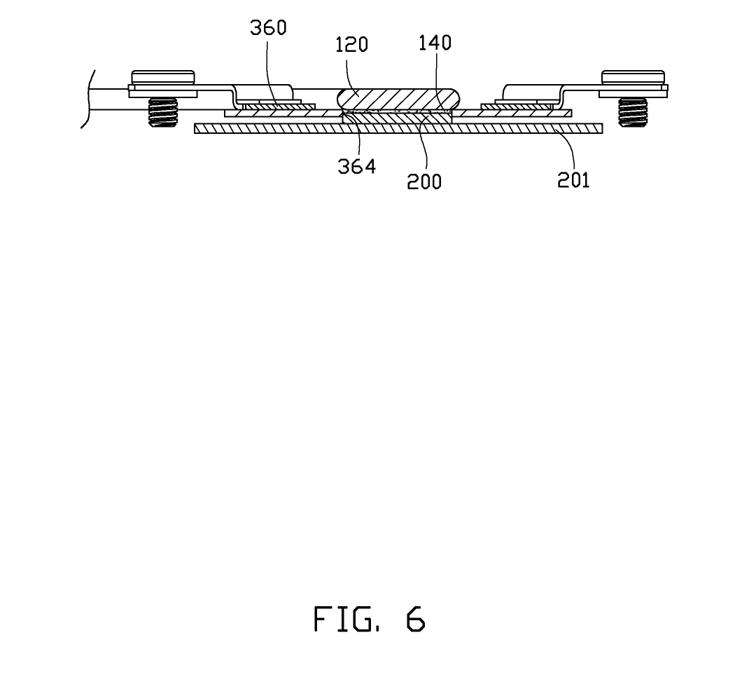

Referring to FIG. 4-6, a heat sink 300 in accordance with a second embodiment is shown. The difference between the heat sink 300 and the heat sink 100 is an arrangement of a fixing plate 360. The base portion of the fixing plate 360 defines an opening 364. A size of the opening 362 corresponds to a size of the electronic element 200 and the conducting member 140, and the opening 362 receives the electronic element 200 and the conducting member 140. The conducting member 140 is applied onto a portion of the heat pipe 120 exposed via the opening 364. After assembly, because the electronic element 200 is received in the opening 364 and abuts the conducting member 140, and because the fixing plate 360 does not cover the top surface of the heat pipe 120, a thickness of the fixing plate 360 is further reduced compared to the heat sink 100 of the first embodiment.

Although information as to, and advantages of, the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A heat sink for dissipating heat generated by an electronic element, comprising:
a heat pipe; and
a conducting member for transferring heat generated by the electronic element abutting the conducting member to the heat pipe;
wherein the conducting member is formed by applying solder on a surface of the heat pipe facing the electronic element to reduce the thickness of the heat sink.

2. The latching assembly of claim 1, wherein the thickness of the conducting member is less than 0.04 mm.

3. The heat sink of claim 1, further comprising a fixing plate for latching the heat pipe to the electronic element.

4. The heat sink of claim 3, wherein the fixing plate is secured to a surface of the heat pipe opposite to the conducting member.

5. The heat sink of claim 3, wherein the fixing plate is secured to opposite sides of the heat pipe.

6. The heat sink of claim 3, wherein the fixing plate is secured to a surface of the heat pipe coated the conducting member.

7. The heat sink of claim 6, wherein the fixing plate defines an opening for receiving the electronic element, the conducting member is formed by applying solder on a portion of the heat pipe being exposed via the opening.

8. The heat sink of claim 1, further comprising a heat-dissipating module, wherein the heat-dissipating module is secured to an end of the heat pipe away from the electronic element.
